(19) United States
(12) Patent Application Publication
(10) Pub. No.: US 2009/0115640 A1
(43) Pub. Date: May 7, 2009

(54) METALLIC KEYPAD ASSEMBLY HAVING RIPPLE LUSTER

(76) Inventors: Che-Tung Wu, Gueishan (TW); Chih-Ho Hsu, Gueishan (TW); Kai-Jie Taso, Gueishan (TW)

Correspondence Address: HDLS Patent & Trademark Services, P.O. BOX 220746, CHANTILLY, VA, 20153-0746, US

(21) Appl. No.: 11/946,479

(22) Filed: Nov. 28, 2007

(30) Foreign Application Priority Data
Nov. 7, 2007 (TW) 096218755

(51) Int. Cl. H03M 11/00

(52) U.S. Cl. 341/22

(57) ABSTRACT

A metallic keypad assembly having a ripple luster includes an elastic layer, an adhesive layer, a metallic keypad, an electroplated layer and a pattern layer. The elastic layer has a carrier. The carrier is provided thereon with a plurality of protrusions. The adhesive layer is provided on one side surface of the carrier. The metallic keypad is provided on one side surface of the adhesive layer and has a thin plate thereon. The plate is provided thereon with a first hollowed portion and a second hollowed portion. The first hollowed portion defines a pressing region of a key, and the second hollowed portion is set as an icon on the surface of the pressing region. The electroplated layer is provided on one side surface of the metallic keypad and penetrates into the first hollowed portion and the second hollowed portion. The pattern layer is provided on one side surface of the electroplated layer to seal and fill the first hollowed portion and the second hollowed portion. When external light illuminates the pattern layer of the metallic keypad, the pattern layer generates a reflective effect of a ripple luster.

### BACKGROUND OF THE INVENTION

1. Field of the Invention

The present invention relates to a keypad panel, and in particular to a metallic keypad assembly.

2. Description of Prior Art

Keypad panel has become a necessary hardware for an electronic device. The surface of the keypad panel is provided with numerals, characters, phonetic symbols, roots for an input method and various functional icons, so that a user can input data or perform various functions of the electronic device. Therefore, for a handheld electronic device, the keypad panel is a very important input means.

For example, a conventional metallic keypad on an electronic device is shown in FIGS. 1(a) to 1(f) (Japanese Laid-Open Patent Publication No. 2007-134071). In manufacturing the metallic keypad 10a disclosed in FIG. 1, a metallic plate 1a is prepared first, and the metallic plate 1a is attached on a transparent plastic film 2a. Then, the metallic plate 1a is made to have a hollowed portion 3a. The surface of the metallic plate 1a is formed with a transparent resin layer 4a. The bottom surface of the transparent plastic film 2a is formed with a transparent elastic layer 5a. In manufacturing the transparent elastic layer 5a, via a hot pressing process, the transparent plastic film 2a and the transparent elastic layer 5a are compressed into the hollowed portion 3a together, thereby forming a separating line 21a for separating the metallic keypads. Then, a light-emitting layer 6a is attached to the bottom of the transparent elastic layer 5a.

In manufacturing the above metallic keypad 10a, since the transparent plastic film 2a and the transparent elastic layer 5a are compressed into the hollowed portion 3a together, the pressing force and the heating temperature should be properly controlled during the hot pressing process. Otherwise, the transparent plastic film 2a and the transparent elastic layer 5a cannot be compressed into the hollowed portion 3a completely, causing defective products. Even, during the process of compressing the transparent plastic film 2a and the transparent elastic layer 5a into the hollowed portion 3a, the transparent plastic film 2a may rub and pull the wall faces and chamfers of the hollowed portion 3a, causing the breakage of the transparent plastic film 2a easily and the difficulty in manufacture.

Next, gaps are generated easily between the transparent plastic film 2a compressed into the hollowed portion 3a and the wall face of the hollowed portion 3a. The gaps may be filled by dusts or penetrated by liquid, so that the metallic keypads cannot be pressed smoothly or an internal short circuit may occur.

Further, the surface of the transparent resin layer 4a formed on the metallic plate 1a is a flat surface, which merely provides a protective effect for the metallic plate 1a without any reflective effect of a particular luster. Therefore, the external appearance and the overall visual effect of the metallic keypad 10a are dull.

### SUMMARY OF THE INVENTION

In view of the above drawbacks, the present invention is to provide a novel and simple metallic keypad assembly that allows metallic keypads to be manufactured easily and also makes the surface of the metallic keypad to have a reflective effect of a ripple luster.

The present invention is to provide a metallic keypad assembly having a ripple luster, which includes an elastic layer, an adhesive layer, a metallic keypad, an electroplated layer and a pattern layer. The elastic layer has a carrier. One side surface of the carrier is provided with a plurality of protrusions. The adhesive layer is provided on one side surface of the carrier for binding the metallic keypad. The metallic keypad is provided on one side surface of the adhesive layer and has a thin plate thereon. The plate is provided thereon with a first hollowed portion and a second hollowed portion. The first hollowed portion encircles a pressing region of a keypad via lines, and the second hollowed portion is set as an icon on the surface of the pressing region. The electroplated layer is provided on one side surface of the metallic keypad and penetrates into the first hollowed portion and the second hollowed portion. The pattern layer is provided on one side surface of the electroplated layer to seal and fill the first hollowed portion and the second hollowed portion.

### BRIEF DESCRIPTION OF THE DRAWINGS

FIGS. 1(a) to 1(f) are structural views showing a procedure for manufacturing a traditional metallic keypad;

FIG. 2 is a schematic view showing the external appearance of the metallic keypad of the present invention;

FIG. 3 is a side cross-sectional view showing the metallic keypad of the present invention;

FIG. 4 is a schematic view showing the metallic keypad of the present invention being used in a circuit board of an electronic device;

FIG. 5 is a schematic view showing an operating state in FIG. 4;

FIG. 6 is a schematic view showing the metallic keypad of the present invention being used in a mobile phone;

FIG. 7 is a schematic view showing the metallic keypad of the present invention being used in a personal digital assistant (PDA); and

FIG. 8 is a schematic view showing the metallic keypad of the present invention being used in an automobile stereo panel.

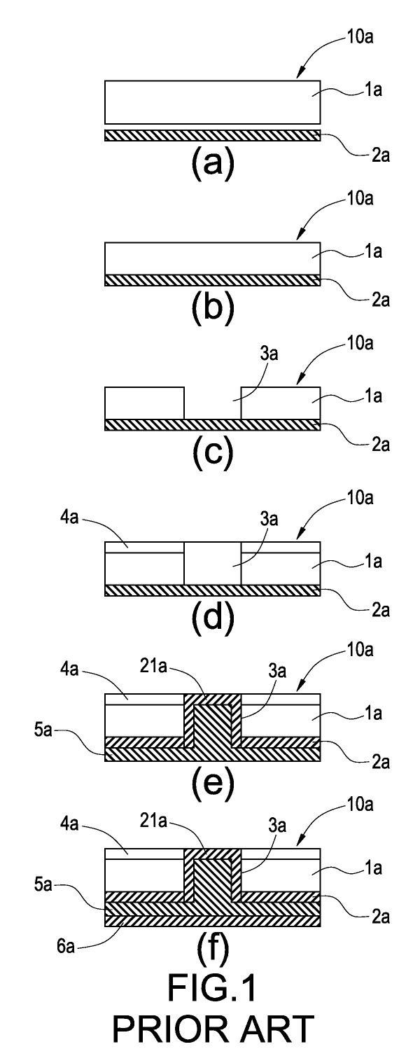

### DETAILED DESCRIPTION OF THE INVENTION

The detailed description and the technical contents of the present invention will be explained with reference to the accompanying drawings.

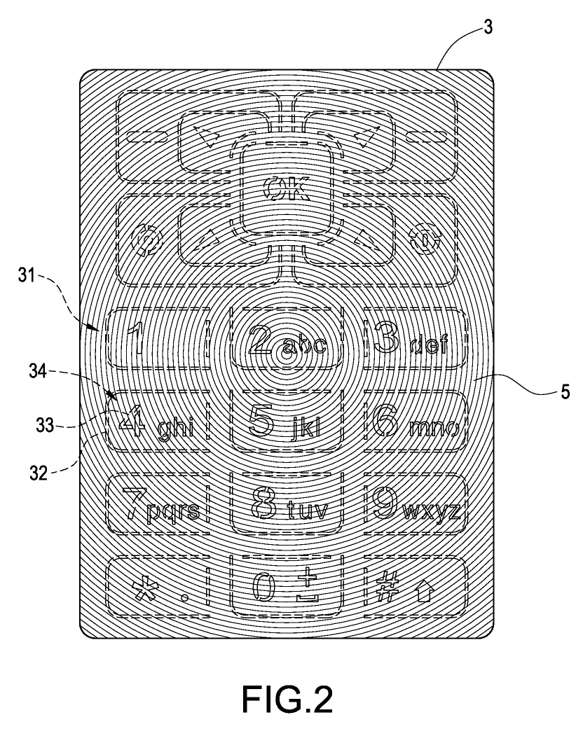

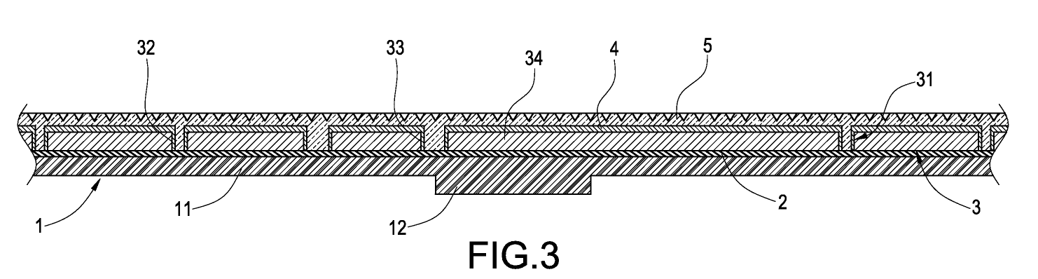

FIG. 2 is a schematic view showing the external appearance of the metallic keypad of the present invention, and FIG. 3 is a side cross-sectional view showing the metallic keypad of the present invention. As shown in these figures, the metallic keypad assembly having a ripple luster in accordance with the present invention includes an elastic layer 1, an adhesive layer, a metallic keypad 3, an electroplated layer 4 and a pattern layer 5.

The elastic layer 1 is made of a transparent rubber material and has a carrier 11 thereon. One side surface of the carrier 11 is provided thereon with a plurality of protrusions 12.

The adhesive layer 2 is provided on one side surface of the carrier 11 for binding the metallic keypad 3.

The metallic keypad 3 is provided on one side surface of the adhesive layer 2 and is made of stainless steel (SUS) or Al—Mg alloy to form a thin plate 31. The plate 31 is provided thereon with a first hollowed portion 32 and a second hollowed portion 33. The first hollowed portion 32 encircles a pressing region 34 of a key via lines, and the second hollowed portion 33 is set as an icon on the surface of the pressing region 34. The icon includes any one of numerals (0 to 9), characters (A to Z), special symbols (e.g., “#”, “*”, “.” etc.), dialing icon, ending icon and navigational symbols.

The electroplated layer 4 is provided on one side surface of the metallic keypad 3 and penetrates into the first hollowed portion 32 and the second hollowed portion 33. The electroplated layer is made of a metallic material such as nickel.

A pattern layer 5 is provided on one side surface of the electroplated layer 4 to seal and fill the first hollowed portion 32 and the second portion 33. The pattern layer 5 is made by means of injecting a thermoplastic material such as thermoplastic polyurethane (TPU) or thermoplastic elastomer (TPE) into a mold, thereby forming a spinning having a ripple luster. Further, the pattern layer 5 also forms a protective layer for the metallic keypad 3.

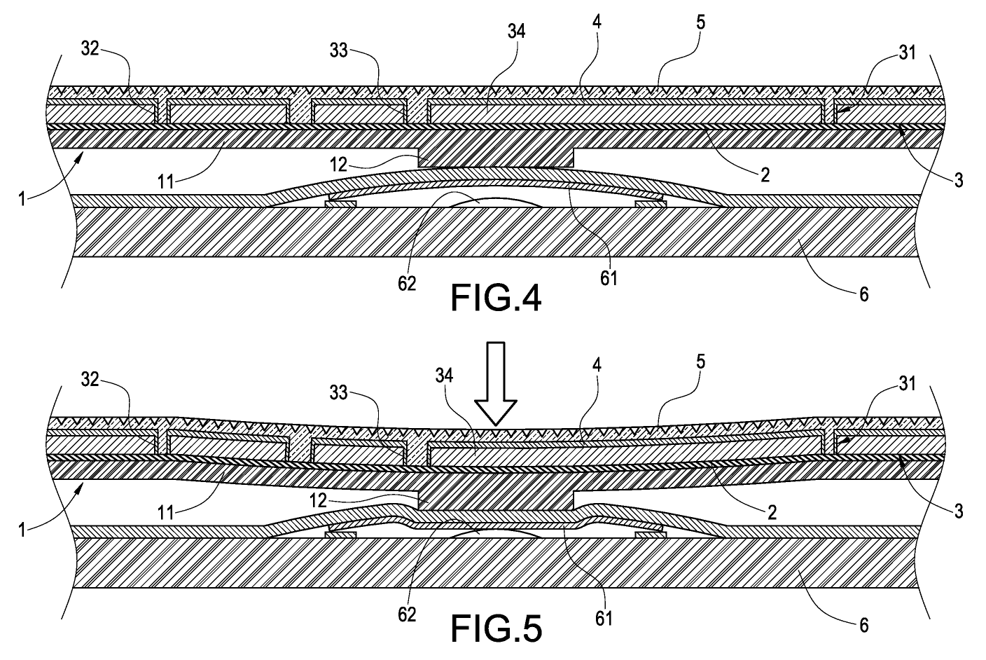

FIG. 4 is a schematic view showing the metallic keypad of the present invention being used in a circuit board of an electronic device, and FIG. 5 is a schematic view showing an operating state in FIG. 4. As shown in this figure, when the pressing region 34 of the metallic keypad 3 is pressed by an external force, the pressing of the pressing region 34 causes the protrusion 12 of the elastic layer 1 to press an elastic piece 61 of a circuit board 6, so that the elastic piece 61 is deformed to contact a conductive point 62 of the circuit board 6, thereby generating a conductive signal output.

When the surface of the pressing region 34 is not pressed by an external force, the elasticity of the materials of the metallic keypad 3 and the elastic layer 1 allows the pressing region 34 to rise automatically, thereby returning to its original state.

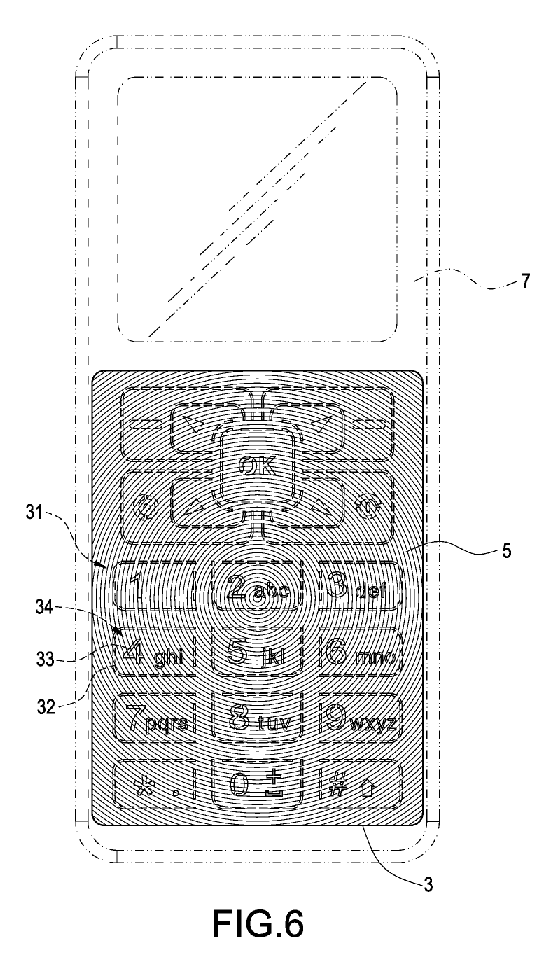

With reference to FIG. 6, it is a schematic view showing the metallic keypad of the present invention being used in a mobile phone. As shown in this figure, after the metallic keypad 3 of the present invention is manufactured completely, it can be applied to a mobile phone 7. When the light illuminates the pattern layer 5 of the metallic keypad 3, the pattern layer 5 generates a reflective effect of a ripple luster, thereby increasing the aesthetic feeling of the mobile phone 7. Further, the pattern layer 5 can protect the surface of the metallic keypad 3 from suffering damage due to external rigid objects.

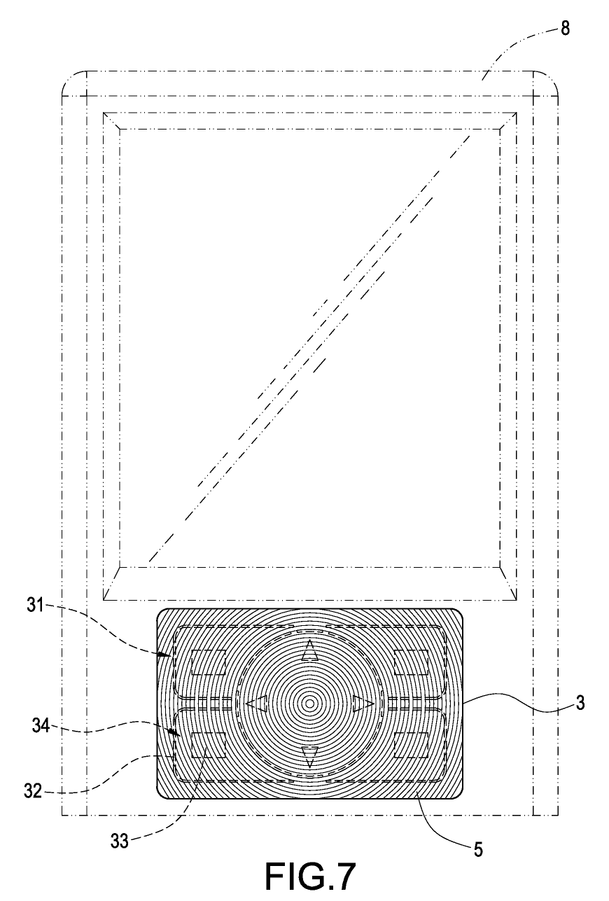

With reference to FIG. 7, it is a schematic view showing the metallic keypad of the present invention being used in a personal digital assistant (PDA). As shown in this figure, after the metallic keypad 3 of the present invention is manufactured completely, in addition to the mobile phone 7, it can be applied to a personal digital assistant (PDA) 8. When the light illuminates the pattern layer 5 of the metallic keypad 3, the pattern layer 5 generates a reflective effect of a ripple luster, thereby increasing the aesthetic feeling of the personal digital assistant (PDA) 8.

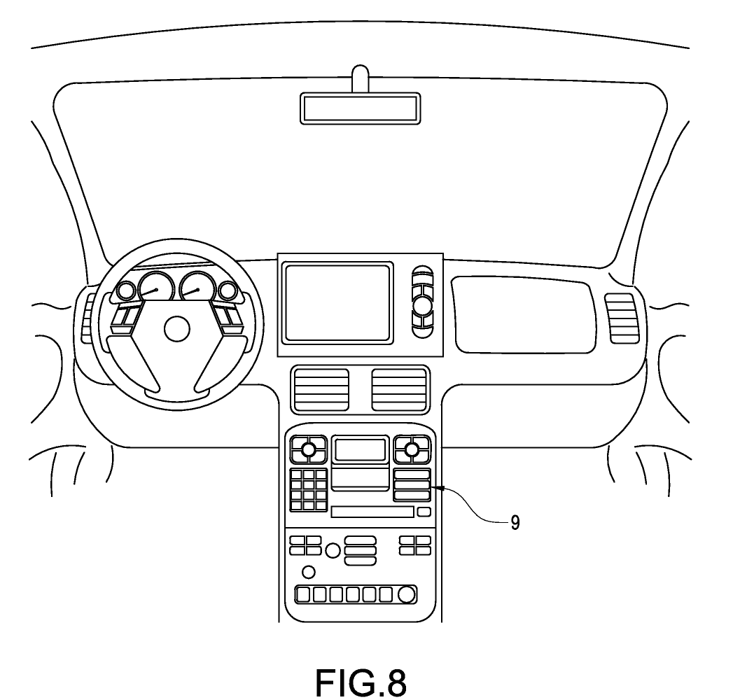

With reference to FIG. 8, it is a schematic view showing the metallic keypad of the present invention being used in an automobile stereo panel. As shown in this figure, in addition to the mobile phone 7 and the personal digital assistant (PDA) 8, the metallic keypad assembly of the present invention can be mounted on an automobile stereo panel 9, thereby controlling the operations of an air conditioning system, audio-video system and satellite navigation system.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A metallic keypad assembly having a ripple luster, arranged on an electronic device and comprising:
an elastic layer having a carrier thereon, one side surface of the carrier being provided with a plurality of protrusions;
a metallic keypad provided on one side surface of the carrier and having a thin plate thereon, the plate being provided thereon with a first hollowed portion and a second hollowed portion, the first hollowed portion being set as a pressing region, the second hollowed portion being set as an icon on the keypad surface; and
a pattern layer provided on one side surface of the metallic keypad to seal and fill the first hollowed portion and the second hollowed portion.

2. The metallic keypad assembly having a ripple luster according to claim 1, wherein the elastic layer is made of a rubber material.

3. The metallic keypad assembly having a ripple luster according to claim 1, wherein the metallic keypad is made of stainless steel (SUS) or Al—Mg alloy.

4. The metallic keypad assembly having a ripple luster according to claim 1, wherein the first hollowed portion encircles a pressing region via lines.

5. The metallic keypad assembly having a ripple luster according to claim 1, wherein the icon comprise any one of numerals, characters, special symbols, dialing icon, ending icon and navigational symbols.

6. The metallic keypad assembly having a ripple luster according to claim 5, wherein the special symbol comprises “#”, “*”, “.” etc.

7. The metallic keypad assembly having a ripple luster according to claim 1, further comprising an adhesive layer provided between the elastic layer and the metallic keypad, the adhesive layer allowing the elastic layer to be bound with the metallic keypad.

8. The metallic keypad assembly having a ripple luster according to claim 1, wherein the pattern layer is made of thermoplastic polyurethane (TPU) or thermoplastic elastomer (TPE).

9. The metallic keypad assembly having a ripple luster according to claim 1, wherein the ripple on the surface of the pattern layer is a spinning.

10. The metallic keypad assembly having a ripple luster according to claim 1, wherein the pattern layer forms a protective layer for the metallic keypad.

11. The metallic keypad assembly having a ripple luster according to claim 1, further comprising an electroplated layer provided between the metallic keypad and the pattern layer.

12. The metallic keypad assembly having a ripple luster according to claim 11, wherein the electroplated layer penetrates into the first hollowed portion and the second hollowed portion.

13. The metallic keypad assembly having a ripple luster according to claim 11, wherein the electroplated layer is made of a metallic material.
